(19) United States
(12) Patent Application Publication
(10) Pub. No.: US 2019/0148918 A1
(43) Pub. Date: May 16, 2019

(54) CONFIGURING AN EMITTER PATTERN FOR AN EMITTER ARRAY TO AVOID A POTENTIAL DISLOCATION LINE

(71) Applicant: Lumentum Operations LLC, Milpitas, CA (US)

(72) Inventors: Matthew Glenn Peters, Menlo Park, CA (US); David Venables, Milpitas, CA (US); Eric R. Hegblom, Sunnyvale, CA (US); Ajit Vijay Barve, San Jose, CA (US)

(21) Appl. No.: 16/146,180

(22) Filed: Sep. 28, 2018

Related U.S. Application Data
(60) Provisional application No. 62/586,000, filed on Nov. 14, 2017.

(51) Int. Cl. H01S 5/42; H01S 5/183

(52) U.S. Cl. CPC H01S 5/423; H01S 5/18308; H01S 5/18394

(57) ABSTRACT

A die may comprise a plurality of adjacent emitters and a potential dislocation line. The plurality of adjacent emitters and the potential dislocation line may be offset from each other within a range of angles based on a relative rotation of the plurality of adjacent emitters and the potential dislocation line.

### RELATED APPLICATION

This application claims priority under 35 U.S.C. § 119 to U.S. Provisional Patent Application No. 62/586,000, filed on Nov. 14, 2017, the content of which is incorporated by reference herein in its entirety.

### TECHNICAL FIELD

The present disclosure relates to an emitter array and, more particularly, to configuration of an emitter pattern on an emitter array.

### BACKGROUND

A vertical-emitting device, such as a vertical cavity surface emitting laser (VCSEL), is a laser in which a beam is emitted in a direction perpendicular to a surface of a substrate (e.g., vertically from a surface of a semi-conductor wafer). Multiple vertical-emitting devices may be arranged in an array with a common substrate.

### SUMMARY

According to some possible implementations, a die may comprise: a plurality of adjacent emitters; and a potential dislocation line, wherein the plurality of adjacent emitters and the potential dislocation line are offset from each other within a range of angles based on a relative rotation of the plurality of adjacent emitters and the potential dislocation line.

According to some possible implementations, a vertical cavity surface emitting laser (VCSEL) array may comprise: a plurality of adjacent VCSELs; and a potential dislocation line, wherein the plurality of adjacent VCSELs and the potential dislocation line are offset from each other based on a relative rotation of a die associated with the VCSEL array and the potential dislocation line.

According to some possible implementations, a wafer may comprise: a plurality of die that include a plurality of adjacent emitters; and a potential dislocation line, wherein the plurality of adjacent emitters and the potential dislocation line are offset from each other based on a relative rotation of the plurality of adjacent emitters and the potential dislocation line.

### BRIEF DESCRIPTION OF THE DRAWINGS

FIGS. 1A and 1B are diagrams depicting a top-view of an example vertical-emitting device and a cross-sectional view of the example vertical-emitting device, respectively;

FIG. 2 is a diagram depicting a top view of an emitter array that includes a relative rotation between a potential dislocation line and an emitter pattern of the emitter array;

FIG. 3 is a diagram depicting a first top-view of a prior emitter array that includes a prior alignment of a first emitter pattern and a first potential dislocation line and a second top-view of another emitter array that includes a relative rotation of a second emitter pattern and a second potential dislocation line; and

FIG. 4 is a diagram depicting top-views of various emitter arrays that include relative rotations of various emitter patterns and potential dislocation lines.

### DETAILED DESCRIPTION

The following detailed description of example implementations refers to the accompanying drawings. The same reference numbers in different drawings may identify the same or similar elements.

An emitter array may be arranged on a die in regular evenly spaced patterns (e.g., for optimal power and temperature profile across the emitter array). Often, an emitter pattern of the emitter array is aligned with potential dislocation lines of the die (e.g., lines along which dislocations are likely to propagate). In some cases, when a defect in the die propagates along a potential dislocation line, the defect may intersect one or more emitters of the emitter array based on the emitter pattern of the emitter array being aligned with a potential dislocation line (e.g., thereby causing the one or more emitters to fail, to produce less than a threshold amount of optical output, to produce less than a threshold amount of power, etc.). If a threshold quantity of emitters are intersected (or if a threshold quantity of adjacent emitters are intersected), the defect may cause a failure of the entire emitter array.

Some implementations described herein provide a die where emitter (e.g., adjacent emitters) on the die and a potential dislocation line of the die are offset from each other within a range of angles based on a relative rotation of the emitters and the potential dislocation line. In this way, the relative rotation of the emitters and the potential dislocation line reduces a quantity of emitters (or adjacent emitters) that could be intersected by a defect propagating along the potential dislocation line. This improves a reliability of an emitter array by reducing or eliminating a likelihood that the emitter array fails due to propagation of a defect. In addition, this conserves costs associated with replacing an emitter array when a threshold quantity of emitters and/or a threshold quantity of adjacent emitters fail. Further, this improves a quality of an emitter array by reducing or eliminating potential intersection of a defect with the emitters of the emitter array.

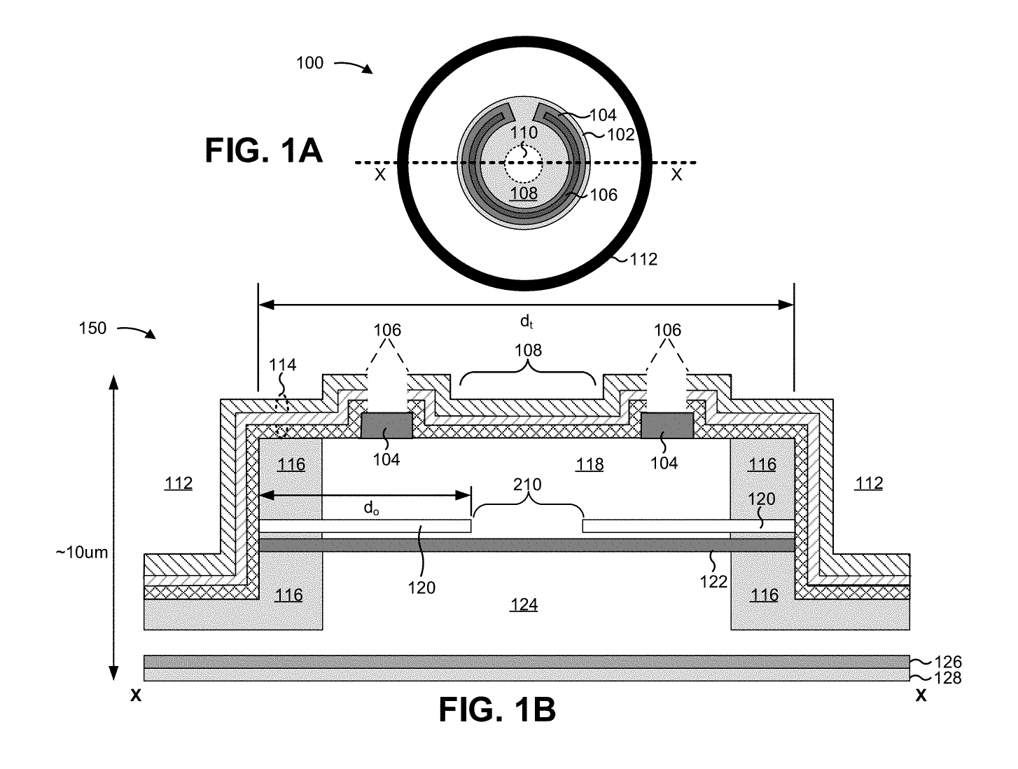

FIGS. 1A and 1B are diagrams depicting a top-view of an example emitter 100 and a cross-sectional view 150 of example emitter 100, respectively. As shown in FIG. 1A, emitter 100 may include a set of emitter layers constructed in an emitter architecture. In some implementations, emitter 100 may correspond to one or more vertical-emitting devices described herein.

As shown in FIG. 1A, emitter 100 includes an implant protection layer 102 that is circular in shape in this example. In some implementations, implant protection layer 102 may have another shape, such as an elliptical shape, a polygonal shape, or the like. Implant protection layer 102 is defined based on a space between sections of implant material (not shown) included in emitter 100. As shown by the medium gray area in FIG. 1A, emitter 100 includes a P-Ohmic metal layer 104 that is constructed in a partial ring-shape (e.g., with an inner radius and an outer radius). As shown, P-Ohmic metal layer 104 is positioned concentrically over implant protection layer 102 (i.e., the outer radius of P-Ohmic metal layer 104 is less than or equal to the radius of implant protection layer 102). Such configuration may be used, for example, in the case of a P-up/top-emitting emitter 100. In the case of a bottom-emitting emitter 100, the configuration may be adjusted as needed.

As further shown in FIG. 1A, emitter 100 includes a dielectric via opening 106 that is formed (e.g., etched) on a dielectric passivation/mirror layer (not shown) that covers P-Ohmic metal layer 104. As shown, dielectric via opening 106 is formed in a partial ring-shape (e.g., similar to P-Ohmic metal layer 104) and is formed concentrically over P-Ohmic metal layer 104 such that the dielectric passivation/mirror layer contacts P-Ohmic metal layer 104. In some implementations, dielectric opening 106 and/or P-Ohmic metal layer 104 may be formed in another shape, such as a full ring-shape.

As further shown, emitter 100 includes an optical aperture 108 in a portion of the emitter within the inner radius of the partial ring-shape of P-Ohmic metal layer 104. Emitter 100 emits a laser beam via optical aperture 108. As further shown, emitter 100 also includes a current confinement aperture 110 (e.g., an oxide aperture formed by an oxidation layer (not shown) of emitter 100). Current confinement aperture 110 is formed below optical aperture 108.

As further shown in FIG. 1A, emitter 100 includes an oxidation trench 112 around a circumference of implant protection layer 102. How close oxidation trench 112 can be positioned relative to the optical aperture 108 is dependent on the application, and is typically limited by implant protection layer 102, P-Ohmic metal layer 104, dielectric via opening 106, and manufacturing tolerances.

The number and arrangement of layers shown in FIG. 1A are provided as an example. In practice, emitter 100 may include additional layers, fewer layers, different layers, or differently arranged layers than those shown in FIG. 1A. For example, while emitter 100 includes a single oxidation trench 112, in practice, other designs are possible, such as a set of oxidation trenches 112, spaced (e.g., equally, unequally) around a circumference of implant protection layer 102, that includes six oxidation trenches 112, a compact emitter that includes five oxidation trenches 112, seven oxidation trenches 112, and/or the like. As another example, while emitter 100 is a circular emitter design, in practice, other designs are possible, such as a rectangular emitter, a hexagonal emitter, an elliptical emitter, or the like. Additionally, or alternatively, a set of layers (e.g., one or more layers) of emitter 100 may perform one or more functions described as being performed by another set of layers of emitter 100, respectively.

Notably, while the design of emitter 100 is described as including a vertical cavity surface emitting laser (VCSEL), other implementations are possible. For example, the design of emitter 100 may apply in the context of another type of optical device, such as a light emitting diode (LED), or another type of vertical emitting (e.g., top emitting or bottom emitting) optical device. Additionally, the design of emitter 100 may apply to emitters of any wavelength, power level, emission profile, or the like. In other words, emitter 100 is not particular to an emitter with a given performance characteristic.

FIG. 1B is an expanded cross-sectional view of emitter 100 described with regard to FIG. 1A. As such, FIG. 1B may be at a different scale than FIG. 1A. As shown in FIG. 1B, the example cross-sectional view may represent a cross-section of emitter 100 that passes through oxidation trench 112 (e.g., as shown by the line labeled “X-X” in FIG. 1A). As shown, emitter 100 may include a backside cathode layer 128, a substrate layer 126, a bottom mirror 124, an active region 122, an oxidation layer 120, a top mirror 118, an implant isolation material 116, a dielectric passivation/mirror layer 114, and a P-Ohmic metal layer 104. As shown, emitter 100 may have a total height that is approximately 10 μm.

Backside cathode layer 128 may include a layer that makes electrical contact with substrate layer 126. For example, backside cathode layer 128 may include an annealed metallization layer, such as an AuGeNi layer, a PdGeAu layer, or the like.

Substrate layer 126 may include a base substrate layer upon which epitaxial layers are grown. For example, substrate layer 126 may include a semiconductor layer, such as a GaAs layer, an InP layer, and/or the like.

Bottom mirror 124 may include a bottom reflector layer of emitter 100. For example, bottom mirror 124 may include a distributed Bragg reflector (DBR).

Active region 122 may include a layer that confines electrons and defines an emission wavelength of emitter 100. For example, active region 122 may be a quantum well.

Oxidation layer 120 may include an oxide layer that provides optical and electrical confinement of emitter 100. In some implementations, oxidation layer 120 may be formed as a result of wet oxidation of an epitaxial layer. For example, oxidation layer 120 may be an Al₂O₃ layer formed as a result of oxidation of an AlAs or AlGaAs layer. Oxidation trench 112 may include openings that allow oxygen (e.g., dry oxygen, wet oxygen) to access the epitaxial layer from which oxidation layer 120 is formed.

Current confinement aperture 110 may include an optically active aperture defined by oxidation layer 120. A size of current confinement aperture 110 may range, for example, from approximately 6.0 μm to approximately 14.0 μm. In some implementations, a size of current confinement aperture 110 may depend on a width of oxidation trench 112 that surrounds emitter 100. For example, oxidation trench 112 may be etched to expose the epitaxial layer from which oxidation layer 120 is formed. Here, before dielectric passivation/mirror layer 114 is deposited, oxidation of the epitaxial layer may occur for a particular distance (e.g., identified as dₒ in FIG. 1B) toward a center of emitter 100, thereby forming oxidation layer 120 and current confinement aperture 110. In some implementations, current confinement aperture 110 may include an oxide aperture. Additionally, or alternatively, current confinement aperture 110 may include an aperture associated with another type of current confinement technique, such as an etched mesa, a region without ion implantation, lithographically defined intra-cavity mesa and regrowth, or the like.

Top mirror 118 may include a top reflector layer of emitter 100. For example, top mirror 118 may include a DBR.

Implant isolation material 116 may include a material that provides electrical isolation. For example, implant isolation material 116 may include an ion implanted material, such as an H implanted material or a Hydrogen/Proton implanted material. In some implementations, implant isolation material 116 may define implant protection layer 102.

Dielectric passivation/mirror layer 114 may include a layer that acts as a protective passivation layer and that acts as an additional DBR. For example, dielectric passivation/mirror layer 114 may include one or more sub-layers (e.g., a SiO2 layer, a Si3N4 layer) deposited (e.g., via chemical vapor deposition) on one or more other layers of emitter 100.

As shown, dielectric passivation/mirror layer 114 may include one or more dielectric via openings 106 that provide electrical access to P-Ohmic metal layer 104. Optical aperture 108 may include a portion of dielectric passivation/mirror layer 114 over current confinement aperture 110 via which light may be emitted.

P-Ohmic metal layer 104 may include a layer that makes electrical contact through which electrical current may flow. For example, P-Ohmic metal layer 104 may include a TiAu layer, a TiPtAu layer, or the like, through which electrical current may flow (e.g., via a bondpad (not shown) that contacts P-Ohmic metal layer 104 through dielectric via openings 106).

In some implementations, emitter 100 may be manufactured using a series of steps. For example, bottom mirror 124, active region 122, oxidation layer 120, and top mirror 118 may be epitaxially grown on substrate layer 126, after which P-Ohmic metal layer 104 may be deposited on top mirror 118. Next, oxidation trench 112 may be etched to expose oxidation layer 120 for oxidation. Implant isolation material 116 may be created via ion implantation, after which dielectric passivation/mirror layer 114 may be deposited. Dielectric via openings 106 may be etched in dielectric passivation/mirror layer 114 (e.g., to expose P-Ohmic metal layer for contact). Plating, seeding, and etching may be performed, after which substrate layer 126 may be thinned and/or lapped to a target thickness. Finally, backside cathode layer 128 may be deposited on a bottom side of substrate layer 126.

The number, arrangement, thicknesses, order, symmetry, or the like, of layers shown in FIG. 1B is provided as an example. In practice, emitter 100 may include additional layers, fewer layers, different layers, differently constructed layers, or differently arranged layers than those shown in FIG. 1B. Additionally, or alternatively, a set layers (e.g., one or more layers) of emitter 100 may perform one or more functions described as being performed by another set of layers of emitter 100.

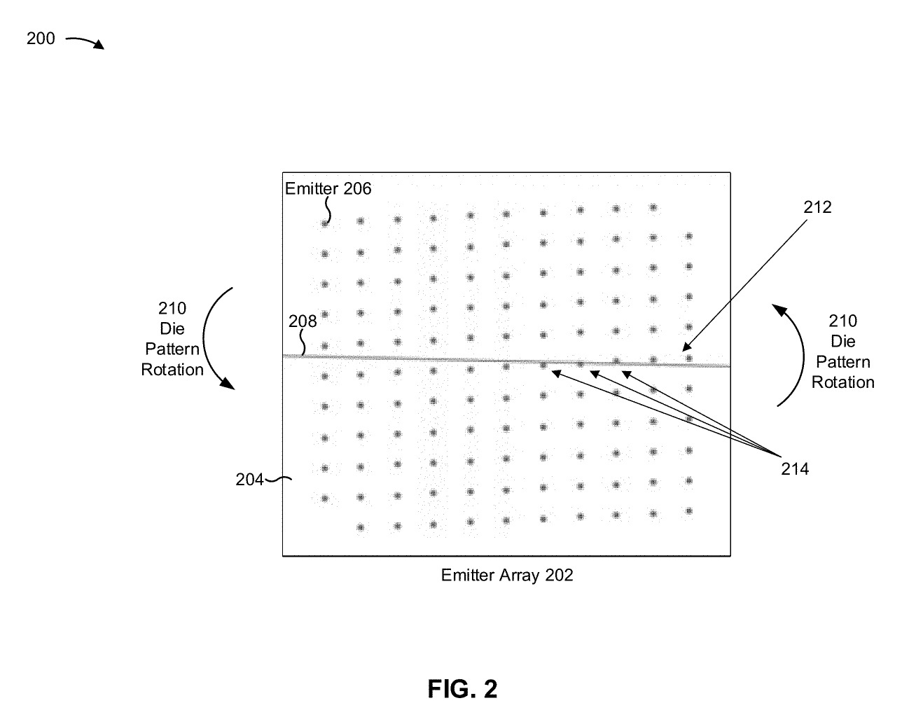

FIG. 2 is a diagram of an example implementation 200 depicting a top view of an emitter array that includes a relative rotation between a potential dislocation line and an emitter pattern of the emitter array. A dislocation may include a discontinuity in an otherwise normal lattice structure of a crystal, a displacement of part of a crystal lattice structure, and/or the like.

As shown in FIG. 2, implementation 200 includes emitter array 202. For example, emitter array 202 may be an emitter array, a VCSEL array, a light-emitting device array, a laser array, and/or the like. As further shown in FIG. 2, emitter array 202 may be formed on die 204 (e.g., a gallium arsenide (GaAs) die). FIG. 2 does not show a wafer associated with die 204 (e.g., a wafer may include other die 204). As further shown in FIG. 2, emitter array 202 may include emitters 206 arranged in a pattern. For example, emitters 206 may be arranged in a two-dimensional regular pattern (e.g., where emitters 206 are arranged in rows and columns of emitters 206).

As further shown in FIG. 2, emitter array 202 may include potential dislocation line 208. For example, potential dislocation line 208 may be a line along which a defect in die 204 could propagate (e.g., a crystallographic axis). As shown by reference number 210, the pattern of emitters 206 and potential dislocation line 208 may be offset from each other via a die pattern rotation. For example, during manufacturing of emitter array 202, die 204 may be have been rotated relative to a mask to generate a relative rotation between die 204 and the pattern of emitters 206. Additionally, or alternatively, the relative rotation between die 204 and the pattern of emitters 206 may be generated via a mask rotation (e.g., rather than a rotation of die 204). For example, during manufacturing of emitter 202, a mask used to manufacture emitters 206 may have been rotated relative to die 204 to generate a relative rotation between die 204 and the pattern of emitters 206.

As shown by reference number 212, the offset between the pattern of emitters 206 and potential dislocation line 208 may be within a range of angles. For example, the range of angles may be one degree to 15 degrees (inclusive). In some implementations, an angle of offset for a particular emitter array 202 may be determined based on a dimension of emitters 206 in emitter array 202, a dimension of a sub-array (e.g., a row of emitters 206, a column of emitters 206, a group of emitters 206 that form a particular shape, and/or the like) of emitter array 202, and/or the like. For example, the angle of offset may be based on a diameter of emitter 206 in emitter array 202 (e.g., a larger relative diameter may correspond to a larger relative angle of offset), a spacing between adjacent emitters 206 (e.g., a larger relative spacing may correspond to a smaller relative angle of offset), a distance between ends of a sub-array of emitter 202 (e.g., ends of a row or a column of emitters 206), a spacing between adjacent sub-arrays (e.g., a larger relative spacing may permit a larger relative angle of offset), a quantity of emitters 206 that need to be offset from potential dislocation line 208 (e.g., a higher relative quantity may correspond to a larger relative angle of offset), and/or the like.

As shown by reference number 214, by offsetting emitters 206 and potential dislocation line 208 from each other, potential dislocation line 208 intersects three emitters 206 in a row of emitters 206 (e.g., three adjacent emitters 206), rather than intersecting all emitters 206 in the row as would be the case if emitter 202 had been manufactured in a normal manner where the pattern of emitters 206 was aligned with potential dislocation line 208. Various criteria could be used to determine the offset such as: reducing intersection of potential dislocation 208 with a threshold quantity of emitters 206 in a row (e.g., a single emitter 206, three or fewer emitters 206, five or fewer emitters 206, and/or the like), a threshold quantity of adjacent emitters 206 in the row (e.g., two adjacent emitters 206, three or fewer adjacent emitters 206, five or fewer adjacent emitters 206, and/or the like), and/or the like. In some implementations, offsetting emitters 206 and potential dislocation line 208 in the manner described herein may prevent emitters 206 from outputting less than approximately 50 percent of an expected amount of power (e.g., based on avoiding potential dislocation line 208).

In this way, a relative rotation between a pattern of emitters 206 (e.g., adjacent emitters 206) and die 204 offsets the pattern of emitters 206 and potential dislocation lines 208 within a range of angles. This reduces a quantity of emitters 206 and/or adjacent emitters 206 that could be intersected by propagation of a defect along potential dislocation line 208. In addition, this reduces a likelihood of a failure of a threshold quantity of emitters 206 and/or adjacent emitters 206, thereby reducing or eliminating a likelihood of failure of a device associated with emitter array 202. Further, this improves a quality of an optical beam from emitter array 202 by facilitating generation of a more uniform optical beam. Further, this reduces a likelihood of failure of emitters 206 without having to increase a distance between adjacent emitters 206 to reduce the likelihood of failure.

As indicated above, FIG. 2 is provided merely as an example. Other examples are possible and may differ from what was described with regard to FIG. 2.

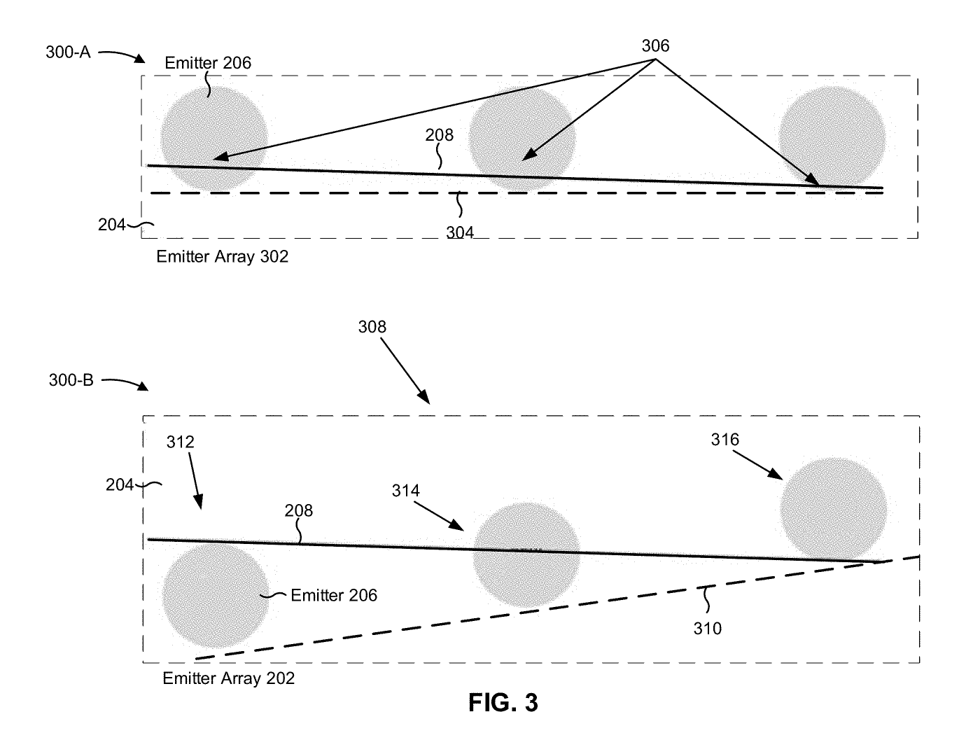

FIG. 3 is a diagram of an examples 300-A and 300-B depicting a first top-view of a prior emitter array that includes a prior alignment of a first emitter pattern and a first potential dislocation line and a second top-view of another emitter array that includes a relative rotation of a second emitter pattern and a second potential dislocation line, respectively. As shown in FIG. 3, example 300-A includes emitter array 302 (e.g., a prior emitter array where emitters 206 of emitter array 302 are aligned with potential dislocation line 208 of emitter array 302—i.e., there is no relative rotation between emitters 206 of emitter array 302 and potential dislocation line 208 of emitter array 302), and example 300-B includes emitter array 202 (e.g., an emitter array that includes a relative rotation between emitters 206 of emitter array 202 and potential dislocation line 208 of emitter array 202).

As shown by reference number 304, emitters 206 of emitter array 302 may be substantially aligned with each other and/or with potential dislocation line 208. For example, rows of emitters 206 of emitter array 302 may be aligned with a crystallographic axis of emitter array 302. As shown by reference number 306, potential dislocation line 208 intersects a set of adjacent emitters 206 (e.g., three adjacent emitters 206) based on emitters 206 being substantially aligned with each other and/or with potential dislocation line 208. In some implementations, potential dislocation line 208 may intersect a threshold quantity of emitters 206 and/or a threshold quantity of adjacent emitters 206 to cause emitter array 302 to fail (e.g., to fail to output a threshold amount of optical power).

Reference number 308 shows a portion of emitter array 202 in contrast to emitter array 302 described above. As shown by reference number 310, emitters 206 of emitter array 202 are not substantially aligned (e.g., are offset from each other). For example, emitters 206 may be offset from each other based on a dislocation angle of potential dislocation line 208, an expected, or maximum, diameter of emitters 206, and/or the distance between emitter centers of emitters 206 of emitter array 202. Continuing with the previous example, adjacent emitters 206 may be offset in a north-south direction by approximately 2.7 micrometers (μm) based on a 1.6 degree dislocation angle of potential dislocation line 208, a 47 μm distance between adjacent emitters 206, and an eight micrometer expected diameter of emitters 206. This may prevent damage to more than two adjacent emitters 206. For example, as shown by reference number 312, potential dislocation line 208 may not intersect a first emitter 206. Additionally, or alternatively, and as another example, potential dislocation line 208 may intersect a second emitter 206 (as shown by reference number 314). Additionally, or alternatively, and as another example, potential dislocation line 208 may intersect an edge of a third emitter 206 (as shown by reference number 316). Continuing with the previous example, although potential dislocation line 208 intersects a portion of the third emitter 206, a defect propagating along potential dislocation line 208 may not cause enough damage to the third emitter 206 to cause the third emitter 206 to fail, to fail to output a threshold amount of optical output, and/or the like.

In some implementations, emitters 206 may be offset by a different amount than that described above. For example, depending on a distance between rows of emitters 206 of emitter array 202, adjacent emitters 206 may be offset in a north-south direction by approximately 5.5 μm. This may prevent any adjacent emitters 206 from being intersected by potential dislocation line 208, thereby further reducing a quantity of emitters 206 that could be intersected by a defect propagating along potential dislocation line 208.

As indicated above, FIG. 3 is provided merely as an example. Other examples are possible and may differ from what was described with regard to FIG. 3.

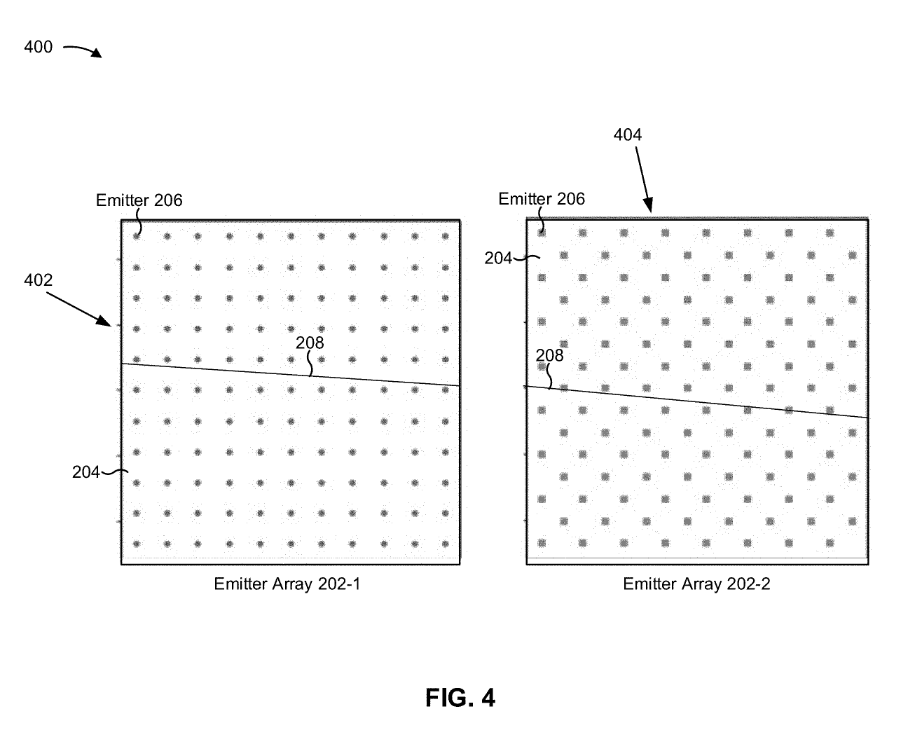

FIG. 4 is a diagram of an example implementation 400 depicting top-views of various emitter arrays that include relative rotations of various emitter patterns and potential dislocation lines. As shown in FIG. 4, implementation 400 includes emitter array 202-1 and emitter array 202-2. Assume for FIG. 4 that emitter arrays 202-1 and 202-2 are configured such that respective patterns of emitters 206 and potential dislocation lines 208 are offset from each other via a relative rotation of the respective patterns of emitters 206 and potential dislocation lines 208.

As shown by reference number 402, emitter array 202-1 may include a rectangular two-dimensional pattern of emitters 206. As shown by reference number 404, emitter array 202-2 may include an offset two-dimensional pattern of emitters 206. In this way, a relative rotation of a pattern of emitters 206 and potential dislocation line 208 can be used with various patterns for emitters 206 to offset emitters 206 from potential dislocation line 208.

As indicated above, FIG. 4 is provided merely as an example. Other examples are possible and may differ from what was described with regard to FIG. 4. For example, the implementations described herein may be applicable to a hexagonal pattern of emitters 206, a pattern of emitters 206 that includes some regularly patterned emitters 206 and some randomly patterned emitters 206, and/or the like.

Although described in the context of an emitter array 202 that includes a regular pattern of emitters 206, the implementations described herein may apply equally to an emitter array 202 that includes a semi-random pattern of emitters 206, a segmented pattern of emitters 206, and/or the like. For example, a pattern of emitters 206 may include a random pattern of emitters 206 and a regular pattern of emitters 206 that are interleaved with each other (e.g., a horizontal line of regularly spaced emitters 206 and/or a vertical line of regularly spaced emitters 206 interleaved with a random pattern of emitters 206). In this case, adjacent emitters 206 of the regular pattern of emitters 206 and a potential dislocation line 208 may be offset from each other to minimize a quantity of emitters 206 of the regular pattern of emitters 206 that intersect the potential dislocation line 208.

In this way, emitters 206 (e.g., adjacent emitters 206) and potential dislocation line 208 may be offset from each other within a range of angles via a relative rotation between emitters 206 and potential dislocation line 208. This reduces a quantity of emitters 206 that could be potentially intersected by a defect in die 204, thereby improving a reliability of emitter array 202. In addition, this reduces or eliminates a need to increase a distance between emitters 206 to reduce a likelihood that emitters 206 are intersected by potential dislocation line 208, thereby maintaining a footprint of emitter array 202. Further, this reduces or eliminates a need for emitter array 202 to be replaced due to a failure of emitters 206 (e.g., due to propagation of a defect along potential dislocation line 208 causing failure of one or more emitters 206), thereby conserving costs related to replacing emitter array 202.

The foregoing disclosure provides illustration and description, but is not intended to be exhaustive or to limit the implementations to the precise form disclosed. Modifications and variations are possible in light of the above disclosure or may be acquired from practice of the implementations.

As used herein, the term component is intended to be broadly construed as hardware, firmware, or a combination of hardware and software.

Some implementations are described herein in connection with thresholds. As used herein, satisfying a threshold may refer to a value being greater than the threshold, more than the threshold, higher than the threshold, greater than or equal to the threshold, less than the threshold, fewer than the threshold, lower than the threshold, less than or equal to the threshold, equal to the threshold, or the like.

Even though particular combinations of features are recited in the claims and/or disclosed in the specification, these combinations are not intended to limit the disclosure of possible implementations. In fact, many of these features may be combined in ways not specifically recited in the claims and/or disclosed in the specification. Although each dependent claim listed below may directly depend on only one claim, the disclosure of possible implementations includes each dependent claim in combination with every other claim in the claim set.

No element, act, or instruction used herein should be construed as critical or essential unless explicitly described as such. Also, as used herein, the articles “a” and “an” are intended to include one or more items, and may be used interchangeably with “one or more.” Furthermore, as used herein, the term “set” is intended to include one or more items (e.g., related items, unrelated items, a combination of related and unrelated items, etc.), and may be used interchangeably with “one or more.” Where only one item is intended, the term “one” or similar language is used. Also, as used herein, the terms “has,” “have,” “having,” or the like are intended to be open-ended terms. Further, the phrase “based on” is intended to mean “based, at least in part, on” unless explicitly stated otherwise.

What is claimed is:

1. A die, comprising:
a plurality of adjacent emitters; and
a potential dislocation line,
wherein the plurality of adjacent emitters and the potential dislocation line are offset from each other within a range of angles based on a relative rotation of the plurality of adjacent emitters and the potential dislocation line.

2. The die of claim 1, wherein the relative rotation is a result of a rotation of a mask used to manufacture the plurality of adjacent emitters relative to the die.

3. The die of claim 1, wherein the relative rotation is a result of a rotation of the die relative to a mask used to manufacture the plurality of adjacent emitters.

4. The die of claim 1, wherein an angle, of the range of angles, is determined based on at least one of:
a diameter of emitters of the plurality of adjacent emitters,
a distance between the emitters of the plurality of adjacent emitters,
a distance from a first end of the plurality of adjacent emitters to a second end of the plurality of adjacent emitters, or
a distance between the plurality of adjacent emitters and another plurality of adjacent emitters.

5. The die of claim 1, wherein the range of angles is from one degree to 15 degrees (inclusive).

6. The die of claim 1, wherein the plurality of adjacent emitters is arranged in a regular two-dimensional pattern.

7. The die of claim 1, wherein the relative rotation causes less than a threshold quantity of emitters, of the plurality of adjacent emitters, to intersect the potential dislocation line.

8. A vertical cavity surface emitting laser (VCSEL) array, comprising:
a plurality of adjacent VCSELs; and
a potential dislocation line,
wherein the plurality of adjacent VCSELs and the potential dislocation line are offset from each other based on a relative rotation of a die associated with the VCSEL array and the potential dislocation line.

9. The VCSEL array of claim 8, wherein the relative rotation is a result of the die being rotated relative to a mask associated with the VCSEL array.

10. The VCSEL array of claim 8, wherein the relative rotation is a result of a mask associated with the VCSEL array being rotated relative to the die.

11. The VCSEL array of claim 8, wherein the relative rotation prevents one dislocation from intersecting a threshold quantity of VCSELs, of the plurality of VCSELs, and prevents the threshold quantity of VCSELs from outputting less than 50 percent of an expected amount of power.

12. The VCSEL array of claim 8, wherein the potential dislocation line is associated with a crystallographic axis of the die.

13. The VCSEL array of claim 8, wherein an angle, of the range of angles, for the relative rotation is based on a quantity of VCSELs, of the plurality of VCSELs, to be offset from the potential dislocation line.

14. The VCSEL array of claim 8, wherein the relative rotation prevents a threshold quantity of VCSELs, of the plurality of VCSELs, from failing due to propagation of a defect along the potential dislocation line.

15. A wafer, comprising:
a plurality of die that include a plurality of adjacent emitters; and
a potential dislocation line,
wherein the plurality of adjacent emitters and the potential dislocation line are offset from each other based on a relative rotation of the plurality of adjacent emitters and the potential dislocation line.

16. The wafer of claim 15, wherein the plurality of adjacent emitters and the plurality of die are offset by an angle within a range of angles,
wherein the angle is based on at least one of:
a dimension of emitters of the plurality of adjacent emitters,
a dimension of the plurality of adjacent emitters, or
a distance between the plurality of adjacent emitters and another plurality of adjacent emitters.

17. The wafer of claim 15, wherein the relative rotation reduces a likelihood that propagation of a defect along the potential dislocation line will cause a threshold quantity of emitters, of the plurality of adjacent emitters, to fail.

18. The wafer of claim 15, wherein the plurality of adjacent emitters form a row of emitters.

19. The wafer of claim 15, wherein the plurality of adjacent emitters form a column of emitters.

20. The wafer of claim 15, wherein the relative rotation causes less than a threshold quantity of emitters, of the plurality of adjacent emitters, to intersect the potential dislocation line.
